(19) United States
(12) Patent Application Publication
(10) Pub. No.: US 2017/0141166 A1
(43) Pub. Date: May 18, 2017

(54) METHOD OF MANUFACTURING ORGANIC LIGHT-EMITTING DISPLAY APPARATUS

(71) Applicant: Samsung Display Co., Ltd., Yongin-si (KR)

(72) Inventors: Taehyung KIM, Yongin-si (KR); Jehyun SONG, Yongin-si (KR); Seho LEE, Yongin-si (KR)

(21) Appl. No.: 15/153,653

(22) Filed: May 12, 2016

(30) Foreign Application Priority Data
Nov. 16, 2015 (KR) 10-2015-0160457

(51) Int. Cl. H01L 27/32; H01L 51/52; H01L 51/56

(52) U.S. Cl. CPC H01L 27/3246; H01L 51/56; H01L 51/5206; H01L 27/3262; H01L 27/1259

(57) ABSTRACT

A method of manufacturing an organic light-emitting apparatus includes: disposing a pixel electrode on a substrate in a display region; disposing a pixel defining layer covering the pixel electrode; exposing the pixel electrode by forming an opening in the pixel defining layer; and ashing residue of the pixel defining layer by using a laser, the residue remaining on the exposed pixel electrode in the opening.

### CROSS-REFERENCE TO RELATED APPLICATION

This application claims priority from and the benefit of Korean Patent Application No. 10-2015-0160457, filed on Nov. 16, 2015, which is hereby incorporated by reference for all purposes as if fully set forth herein.

### BACKGROUND

Field

One or more exemplary embodiments relate to methods of manufacturing an organic light-emitting display apparatus.

Discussion of the Background

Generally, an organic light-emitting display apparatus realizes colors on a principle of light emission by recombining holes and electrons. The organic light-emitting apparatus include a stack structure having an anode, a cathode, and a light-emitting layer between the anode and the cathode. The anode and the cathode provide the hole and the electron to the light-emitting layer, respectively, and they are recombined in the light-emitting layer.

A pixel unit of the organic light-emitting display apparatus includes a red pixel, a green pixel, and a blue pixel as sub-pixels, and a color is expressed by a color combination of these three sub-pixels. The organic light-emitting display apparatus has a structure including a light-emitting layer emitting light of one of red color, green color, and blue color in each pixel, and a color of the pixel unit is expressed by an appropriate combination of the three light colors.

In each of the sub-pixels, a light-emitting region is defined by a pixel defining layer and the light-emitting layer is formed within the defined region.

The above information disclosed in this Background section is only for enhancement of understanding of the background of the inventive concept, and, therefore, it may contain information that does not form the prior art that is already known in this country to a person of ordinary skill in the art.

### SUMMARY

One or more exemplary embodiments provide methods of manufacturing an organic light-emitting apparatus having improved reliability.

Additional aspects will be set forth in the detailed description which follows, and, in part, will be apparent from the disclosure, or may be learned by practice of the inventive concept.

According to one or more exemplary embodiments, a method of manufacturing an organic light-emitting apparatus, the method includes: disposing a pixel electrode on a substrate in a display region; disposing a pixel defining layer covering the pixel electrode; exposing the pixel electrode by forming an opening in the pixel defining layer; and ashing residue of the pixel defining layer by using a laser. The residue remains on the exposed pixel electrode in the opening.

The method may further include: disposing a thin film transistor connected to the pixel electrode; disposing a light-emitting layer on the exposed pixel electrode; and disposing a facing electrode on the light-emitting layer.

The ashing may include ashing residue with the laser by travelling in a zigzag form on the display region.

The ashing may include irradiating the pixel defining layer including the opening with the laser.

Power of the laser is set so as not to remove the whole pixel defining layer but to remove a portion of the pixel defining layer.

The ashing may include selectively irradiating the opening with the laser.

The laser may include Nd:YAG laser.

The laser may have a wavelength in a range from about 266 nm to about 532 nm.

The pixel defining layer may include a polyimide material.

The ashing may exclude a fluorine gas generating process.

The fluorine gas generating process may include a plasma treatment process.

According to one or more exemplary embodiments, a method of manufacturing an organic light-emitting apparatus includes causing, at least in part, a pixel defining layer to be disposed on a first electrode; causing, at least in part, the pixel defining layer to have an opening to expose the first electrode; and causing, at least in part, residue of the pixel defining layer to be eliminated from a surface of the exposed first electrode by irradiating the opening with a laser.

The laser may be irradiated onto a display region of the organic light-emitting display apparatus in a zigzag form, the display region including the pixel defining layer.

The laser may be irradiated onto a surface of the pixel defining layer together with the opening.

The laser may be selectively irradiated onto the opening.

The method may further include causing, at least in part, a light-emitting layer to be disposed on the exposed first electrode; and causing, at least in part, a second electrode to be disposed on the light-emitting layer.

The foregoing general description and the following detailed description are exemplary and explanatory and are intended to provide further explanation of the claimed subject matter.

### BRIEF DESCRIPTION OF THE DRAWINGS

The accompanying drawings, which are included to provide a further understanding of the inventive concept, and are incorporated in and constitute a part of this specification, illustrate exemplary embodiments of the inventive concept, and, together with the description, serve to explain principles of the inventive concept.

FIG. 1 is a plan view of an organic light-emitting display apparatus.

FIG. 2 is a cross-sectional view of a pixel unit according to an exemplary embodiment.

FIGS. 3A through 3E are cross-sectional views for illustrating a process of manufacturing an organic light-emitting display apparatus according to an exemplary embodiments.

FIG. 4 is a perspective view illustrating an exemplary embodiment of ashing.

FIG. 5 is a flowchart illustrating a method of manufacturing an organic light-emitting display device according to an exemplary embodiment.

### DETAILED DESCRIPTION OF THE ILLUSTRATED EMBODIMENTS

In the following description, for the purposes of explanation, numerous specific details are set forth in order to provide a thorough understanding of various exemplary embodiments. It is apparent, however, that various exemplary embodiments may be practiced without these specific details or with one or more equivalent arrangements. In other instances, well-known structures and devices are shown in block diagram form in order to avoid unnecessarily obscuring various exemplary embodiments.

In the accompanying figures, the size and relative sizes of layers, films, panels, regions, etc., may be exaggerated for clarity and descriptive purposes. Also, like reference numerals denote like elements.

When an element or layer is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. For the purposes of this disclosure, “at least one of X, Y, and Z” and “at least one selected from the group consisting of X, Y, and Z” may be construed as X only, Y only, Z only, or any combination of two or more of X, Y, and Z, such as, for instance, XYZ, XYY, YZ, and ZZ. Like numbers refer to like elements throughout. As used herein, the term “and/or” includes any and all combinations of one or more of the associated listed items.

Although the terms first, second, etc. may be used herein to describe various elements, components, regions, layers, and/or sections, these elements, components, regions, layers, and/or sections should not be limited by these terms. These terms are used to distinguish one element, component, region, layer, and/or section from another element, component, region, layer, and/or section. Thus, a first element, component, region, layer, and/or section discussed below could be termed a second element, component, region, layer, and/or section without departing from the teachings of the present disclosure.

Spatially relative terms, such as “beneath,” “below,” “lower,” “above,” “upper,” and the like, may be used herein for descriptive purposes, and, thereby, to describe one element or feature's relationship to another element(s) or feature(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the exemplary term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof.

Various exemplary embodiments are described herein with reference to sectional illustrations that are schematic illustrations of idealized exemplary embodiments and/or intermediate structures. As such, variations from the shapes of the illustrations as a result, for example, of manufacturing techniques and/or tolerances, are to be expected. Thus, exemplary embodiments disclosed herein should not be construed as limited to the particular illustrated shapes of regions, but are to include deviations in shapes that result from, for instance, manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the drawings are schematic in nature and their shapes are not intended to illustrate the actual shape of a region of a device and are not intended to be limiting.

Unless otherwise defined, all terms (including technical and scientific terms) used herein have the same meaning as commonly understood by one of ordinary skill in the art to which this disclosure is a part. Terms, such as those defined in commonly used dictionaries, should be interpreted as having a meaning that is consistent with their meaning in the context of the relevant art and will not be interpreted in an idealized or overly formal sense, unless expressly so defined herein.

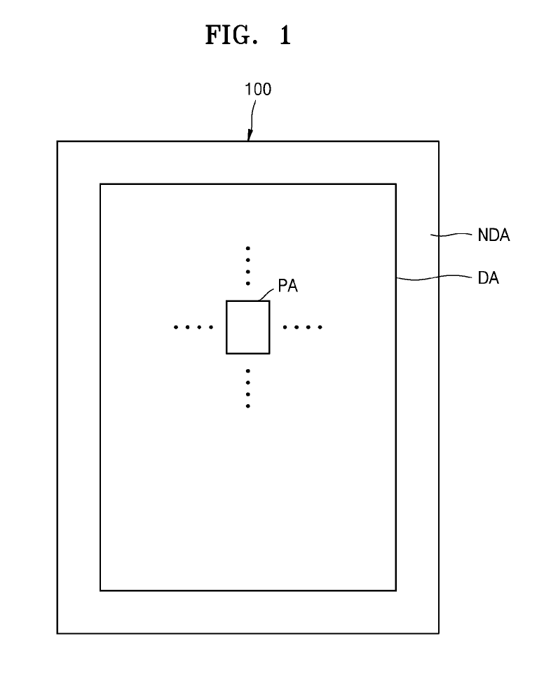

FIG. 1 is a plan view of an organic light-emitting display apparatus 100.

Referring to FIG. 1, the organic light-emitting display apparatus 100 includes a display region DA, on which an image is displayed, and a non-display region NDA adjacent to the display region DA.

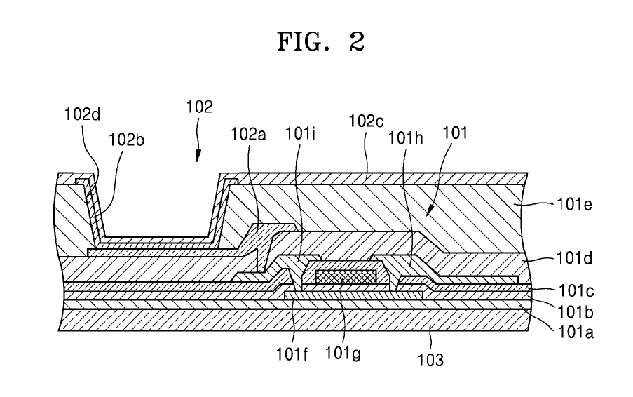

The display region DA includes a plurality of pixel units PA. Each of the plurality of pixel units PA includes at least one organic light-emitting device (refer to 102 in FIG. 2) that emits a light. An image may be displayed by light emitted from the organic light-emitting devices included in the display region DA.

The non-display region NDA may surround the display region DA. The non-display region NDA may include various circuits, such as an injection driver (not shown) and a data driver (not shown) configured to apply and/or transfer signals to the plurality of pixel units PA.

In FIG. 1, it is depicted that the non-display region NDA surrounds the display region DA, but exemplary embodiments are not limited thereto. For example, the non-display region NDA may be on a side of the display region DA, and a dead region may be reduced.

FIG. 2 is a cross-sectional view of a pixel unit according to an exemplary embodiment.

Referring to FIG. 2, each of pixel units PA shown in FIG. 1 includes a thin film transistor 101 and an organic light-emitting device 102.

The thin film transistor 101 includes an active layer 101f on a buffer layer 101a that is adjacent to a substrate 103. In one or more exemplary embodiments, the active layer 101f includes source and drain regions highly doped with an N-type or a P-type dopant. In one or more exemplary embodiments, the active layer 101f may include an oxide semiconductor having, for example, an oxide of group 12, 13, and/or 14 metal selected from the group consisting of zinc, indium, gallium, tin, cadmium, germanium, and hafnium and a combination of these metals. For example, the active layer 101f may include G-I—Z—O[(In₂O₃)a(Ga₂O₃)b(ZnO)c](where a, b, and c respectively are real numbers that satisfy a≧0, b≧0, and c>0). A gate electrode 101g is disposed above the active layer 101f with a gate insulating layer 101b therebetween. An interlayer insulating layer 101c is disposed on the gate insulating layer 101b and the gate electrode 101g. A source electrode 101h and a drain electrode 101i are disposed on the interlayer insulating layer 101c, and are connected to the active layer 101f through holes of the gate insulating layer 101b and the interlayer insulating layer 101c. A passivation film 101d is disposed on the source electrode 101h, the drain electrode 101i, the interlayer insulating layer 101c. The passivation film 101d has a hole exposing the drain electrode 101i to a pixel electrode 102a.

A pixel defining layer 101e formed of a polyimide material is disposed on the pixel electrode 102a and the passivation film 101d. The pixel defining layer 101e may define an emitting area according to an opening 102d. The opening 102d may be provided to the pixel defining layer 101e, and expose a portion of the pixel electrode 102a.

The organic light-emitting device 102 may display image information by emitting emit red, green, and blue lights according to current flow, and includes the pixel electrode 102a that is connected to the drain electrode 101i of the thin film transistor 101, a facing electrode 102c that cover the pixel unit, and a light-emitting layer 102b disposed between the pixel electrode 102a and the facing electrode 102c. The pixel electrode 102a may apply a positive voltage from the drain electrode 101i to the light-emitting layer 102b, and the facing electrode 102c may apply a negative voltage to the light-emitting layer 102b. The positive voltage and the negative voltage may induce the current flow at the light-emitting layer 102b, therefore the organic light-emitting device 102 may emit red, green, or blue.

In one or more exemplary embodiments, a hole injection layer (HIL), a hole transport layer (HTL), an electron transport layer (ETL), and an electron injection layer (EIL) may be stacked adjacent to the light-emitting layer 102b.

In one or more exemplary embodiments, the light-emitting layer 102b may be separately formed in each sub-pixel to form a pixel unit by gathering sub-pixels that emit red, green, and blue lights. In one or more exemplary embodiments, the light-emitting layer 102b may be commonly formed on the regions of the sub-pixels. In this manner, the light-emitting layer 102b may be formed by vertically stacking or mixing layers that include light-emitting materials that emit, for example, red, green, and blue lights. In one or more exemplary embodiments, the light-emitting layer 102b may include a sub-pixel emitting white light. In this manner, a combination of other colors may be possible. Also, the light-emitting layer 102b may further include a color transformation layer that transforms the white light to a light color or a color filter.

In one or more exemplary embodiments, a thin film encapsulating layer (not shown) in which organic films and inorganic films are alternately stacked may be disposed on the facing electrode 102c.

In one or more exemplary embodiments, the substrate 103 may include a flexible material that may be flexibly transformed.

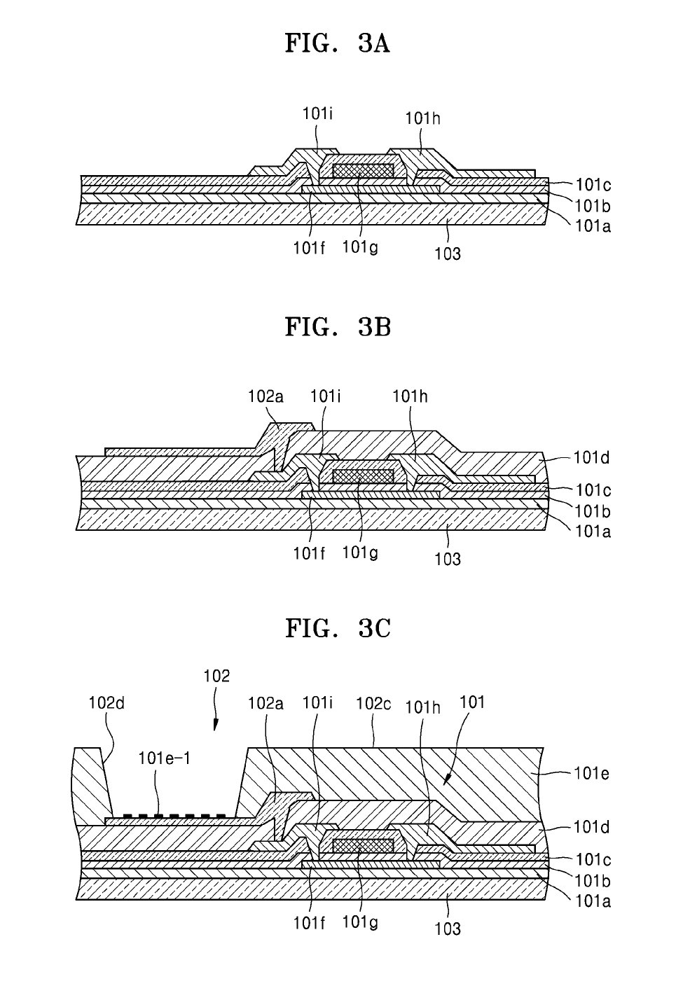

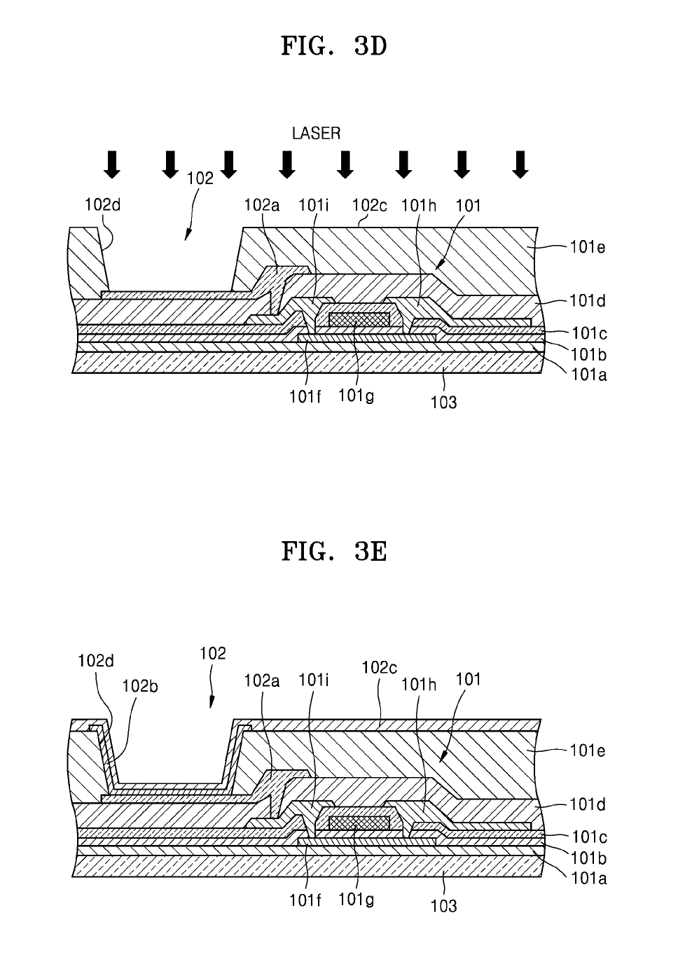

Hereinafter, a method of manufacturing the organic light-emitting display apparatus 100 according to an exemplary embodiment will be described with reference to FIGS. 3A through 3E.

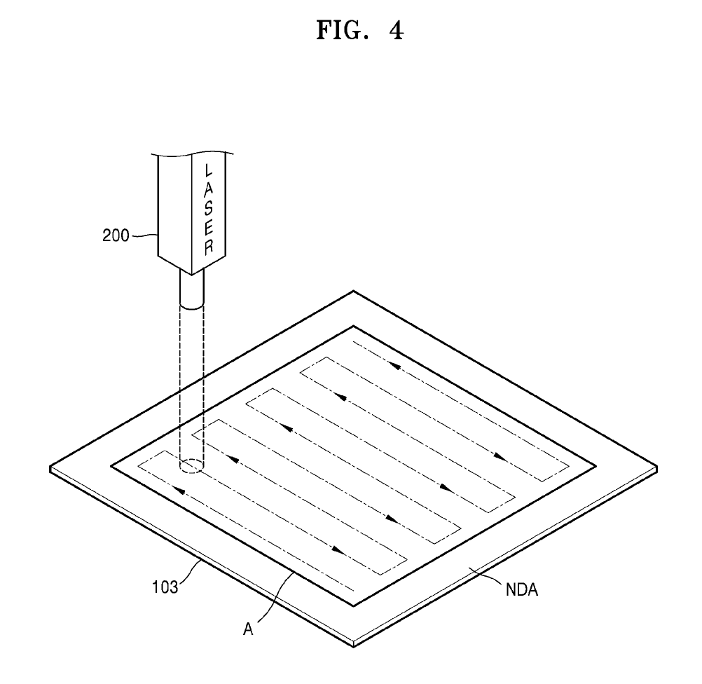

FIGS. 3A through 3E are cross-sectional views for illustrating a process of manufacturing an organic light-emitting display apparatus according to an exemplary embodiments. FIG. 4 is a perspective view illustrating an exemplary embodiment of ashing.

Referring to FIG. 3A, the active layer 101f, the gate electrode 101g, and the source and drain electrodes 101h and 101i of the thin film transistor 101 are formed on the substrate 103.

Referring to FIG. 3B, the pixel electrode 102a of the organic light-emitting device 102 is formed. The pixel electrode 102a may be connected to the drain electrode 101i through a hole of the passivation film 101d.

Referring to FIG. 3C, after forming the pixel defining layer 101e that covers the pixel electrode 102a and the passivation film 101d by using a polyimide material, the opening 102d is formed by, for example, exposing, etching, and cleaning methods using a photoresist to expose a portion of the pixel electrode 102a.

The pixel defining layer 101e in the opening 102d may not be completely removed, but may remain as residue 101e-1 even though the process of forming the opening 102d is finished. That is, the residue 101e-1 may be on the exposed pixel defining layer 101e after the process of forming the opening 102d. The residue 101e-1 may cause non-contact sections between the pixel electrode 102a and the light-emitting layer 102b, thus emitting characteristics of the organic light-emitting display apparatus may be reduced.

Referring to FIG. 3D, a laser ashing process is performed. The residue 101e-1 remaining on the pixel electrode 102a may be removed by burning with a laser. For the ashing operation, the laser of neodymium-doped yttrium aluminum garnet (Nd:Y₃Al₅O₁₂) (ND:YAG) with a wavelength in a range of 266-532 nm may be used.

Referring to FIG. 4, the ashing operation may be performed such that a laser ashing apparatus 200 may irradiate the pixel defining layer 101e with the laser by travelling above the whole display region DA on the substrate 103 in a zigzag type. That is, the laser is irradiated onto not only within the opening 102d, but also onto the whole region of the pixel defining layer 101e. Thus, the residue 101e-1 is removed by the laser ashing, and at the same time, a surface of the pixel defining layer 101e other than the opening 102d may be slightly removed. In one or more exemplary embodiments, power of the laser may be set so as not to remove the whole pixel defining layer 101e but may be set so as to remove a portion of the pixel defining layer 101e, thereby reducing a burden of control of the laser apparatus 200.

In one or more exemplary embodiments, the laser apparatus 200 may be controlled to be “ON” only when it is above the opening 102d so that the surface of the pixel defining layer 101e is not ashed.

According to the exemplary embodiment, the residue 101e-1 on the pixel electrode 102a may be readily and cleanly removed. Therefore, the reduction of light-emitting quality due to the residue 101e-1 may be prevented.

It is assumed that a plasma treatment process is used to remove the residue 101e-1. In this case, a large amount of fluorine gas may be generated, and thus, stains may be generated on a surrounding region and it may cause an unexpected side effect.

According to the exemplary embodiment, the ashing may be processed by using the laser. therefore, some harmful material causing stains on a surrounding region may not be generated and the residue 101e-1 may be efficiently removed.

Referring to FIG. 3E, after the laser ashing process, the light-emitting layer 102b is formed on the exposed pixel electrode 102a in the opening 102d, and then, the facing electrode 102c is formed on the light-emitting layer 102b.

In one or more exemplary embodiments, an encapsulating member (not shown) may be formed on the facing electrode 102c. The encapsulating member may be an insulating film formed of a glass material or a thin film encapsulation. If the encapsulating member is a thin film encapsulation, the encapsulating member may be formed as a monolayer film or a multi-layer film of an inorganic film including, for example, a metal oxide or a metal nitride. In detail, the inorganic film may include one of SiNx, Al₂O₃, SiO₂, and TiO₂.

In one or more exemplary embodiments, the uppermost layer of the thin film encapsulation that is exposed to the outside may include an inorganic film to prevent moisture from penetrating into the organic light-emitting device 102.

In one or more exemplary embodiments, the thin film encapsulation may include at least one sandwich structure in which at least one organic film is between at least two inorganic films. In one or more exemplary embodiments, the thin film encapsulation may include at least one sandwich structure in which at least one inorganic film is between at least two organic films.

In one or more exemplary embodiments, the thin film encapsulation may include a first inorganic film, a first organic film, and a second inorganic film that are sequentially from the top of the organic light-emitting device 102. In one or more exemplary embodiments, the thin film encapsulation may include a first inorganic film, a first organic film, a second inorganic film, a second organic film, and a third inorganic film that are sequentially from the top of the organic light-emitting device 102. In one or more exemplary embodiments, the thin film encapsulation may include a first inorganic film, a first organic film, a second inorganic film, a second organic film, a third inorganic film, a third organic film, and a fourth inorganic film that are sequentially from the top of the organic light-emitting device 102. A halogenated metal layer that includes LiF may be additionally formed between the organic light-emitting device 102 and the first inorganic film.

The halogenated metal layer may prevent the organic light-emitting device 102 from damaging when the first inorganic film is formed by using a sputtering method or a plasma deposition method.

The first organic film has a smaller area than that of the second inorganic film, and also, the second organic film may have the first a smaller area than that of the third inorganic film. Also, the first organic film may be completely covered by the second inorganic film, and the second organic film may be completely covered by the third inorganic film.

In one or more exemplary embodiments, the organic film may include a polymer, preferably one of polyethylene terephthlate, polyimide, polycarbonate, epoxy, polyethylene, and polyacrylate. More preferably, the organic film may include polyacrylate, and in detail, polymerized monomer composition including a diacrylate group monomer and a triacrylate group monomer. A monoacrylate group monomer may further be included in the monomer composition. Also, a well known photoinitiator, such as IPO may further be included in the monomer composition, but the monomer composition is not limited thereto.

According to exemplary embodiments of the present invention, the residue 101e-1 of the pixel defining layer 101e may be cleanly removed from the pixel electrode 102a that is exposed in the opening 102d. Therefore, a stable and uniform contact between the light-emitting layer 102b and the pixel electrode 102a may be ensured.

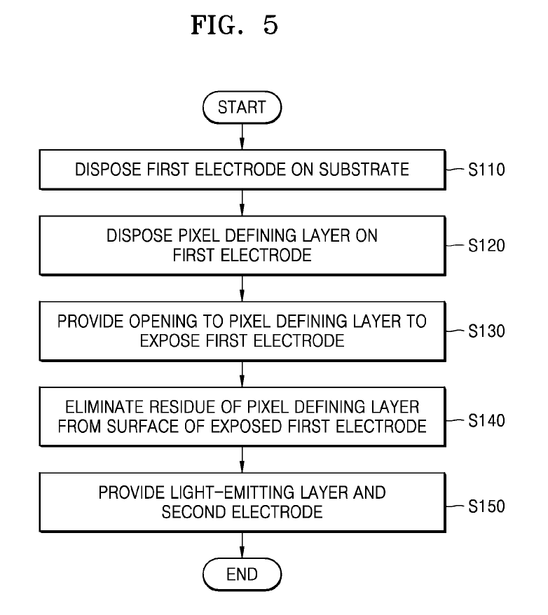

FIG. 5 is a flowchart illustrating a method of manufacturing an organic light-emitting display device according to an exemplary embodiment.

Referring to FIGS. 2 and 5, at step S110, a first electrode is disposed on a substrate 103. The first electrode 102a is provided as the pixel electrode 102a described with reference to FIG. 2. A thin film transistor 101 may be disposed on the substrate 103, then the first electrode 102a may be disposed on the thin film transistor 101. The first electrode 102a may be connected to the thin film transistor 101 and supply voltage and/or current transferred from the thin film transistor 101.

At step S120, a pixel defining layer 101e is disposed on the first electrode 102a. The pixel defining layer 101e may be disposed not only on the first electrode 102a but also on a passivation film 101d. At step S130, opening 102d is provided to the pixel defining layer 101e to expose the first electrode 102a. In one or more exemplary embodiments, the opening 102d is formed by exposing, etching, and cleaning using a photoresist. Residue 101e-1 (See FIG. 3C) of the pixel defining layer 101e may remain when forming the opening 102d.

At step S140, the residue 101e-1 of the pixel defining layer 101e is eliminated from a surface of the exposed first electrode 102a by irradiating the opening 102d with a laser. In one or more exemplary embodiments, the laser may be irradiated onto the surface of the exposed first electrode 102a. In one or more exemplary embodiments, the laser may be irradiated onto a surface of the pixel defining layer 101e as well as the surface of the exposed first electrode 102a.

At step S150, a light-emitting layer 102b and a second electrode is provided. The second electrode is provided as the facing electrode 102c described with reference to FIG. 2. The light-emitting layer 102b may be disposed on the opening 102d, then the second electrode 102c may be disposed on the light-emitting layer 102b. As shown in FIG. 2, the second electrode 102c may be contacted on not only the light-emitting layer 102b but also the pixel defining layer 101e.

According to exemplary embodiments of the present invention, the residue 101e-1 of the pixel defining layer 101e may be removed by using a laser. Therefore, the residue 101e-1 may be effectively removed clean without using a plasma treatment process that may generate fluorine gas, thus preventing a problem of causing stains by fluorine gas. Accordingly, reliability of the organic light-emitting display device may be improved.

Although certain exemplary embodiments and implementations have been described herein, other embodiments and modifications will be apparent from this description. Accordingly, the inventive concept is not limited to such embodiments, but rather to the broader scope of the presented claims and various obvious modifications and equivalent arrangements.

1. (canceled)

2. The method of claim 4, further comprising:
disposing a thin film transistor connected to the pixel electrode;
disposing a light-emitting layer on the exposed pixel electrode; and
disposing a facing electrode on the light-emitting layer.

3. The method of claim 4, wherein the ashing comprises ashing the residue with the laser by travelling in a zigzag form on the display region.

4. A method of manufacturing an organic light-emitting apparatus, comprising:
disposing a pixel electrode on a substrate in a display region;
disposing a pixel defining layer covering the pixel electrode;
exposing the pixel electrode by forming an opening in the pixel defining layer; and
ashing residue of the pixel defining layer by using a laser, the residue remaining on the exposed pixel electrode in the opening,
wherein the ashing comprises irradiating the pixel defining layer including the opening with the laser.

5. The method of claim 4, wherein power of the laser is set so as not to remove the whole pixel defining layer but to remove a portion of the pixel defining layer.

6. (canceled)

7. The method of claim 4, wherein the laser comprises Nd:YAG laser.

8. The method of claim 4, wherein the laser has a wavelength in a range from about 266 nm to about 532 nm.

9. The method of claim 4, wherein the pixel defining layer comprises a polyimide material.

10. The method of claim 4, wherein the ashing excludes a fluorine gas generating process.

11. The method of claim 10, wherein the fluorine gas generating process comprises a plasma treatment process.

12. (canceled)

13. The method of claim 14, the laser is irradiated onto a display region of the organic light-emitting display apparatus in a zigzag form, the display region including the pixel defining layer.

14. A method of manufacturing an organic light-emitting display apparatus, comprising:
causing, at least in part, a pixel defining layer to be disposed on a first electrode;
causing, at least in part, the pixel defining layer to have an opening to expose the first electrode; and
causing, at least in part, residue of the pixel defining layer to be eliminated from a surface of the exposed first electrode by irradiating the opening with a laser,
wherein the laser is irradiated onto a surface of the pixel defining layer together with the opening.

15. (canceled)

16. The method of claim 14, further comprising:
causing, at least in part, a light-emitting layer to be disposed on the exposed first electrode; and
causing, at least in part, a second electrode to be disposed on the light-emitting layer.

17. A method of manufacturing an organic light emitting apparatus, comprising:
disposing a pixel defining layer on a pixel electrode;
forming an opening at the pixel defining layer to expose the pixel electrode; and
ashing residue of the pixel defining layer which remains on the exposed pixel electrode after the forming of the opening,
wherein the ashing comprises irradiating the opening and at least a portion of a remaining surface of the pixel defining layer with a laser.

18. The method of claim 17, wherein power of the laser is set so as not to remove the whole pixel defining layer but to remove a portion of the pixel defining layer.

19. The method of claim 17, wherein the laser is irradiated onto a display region of the organic light-emitting display apparatus in a zigzag form, the pixel defining layer being disposed in the display region.
